(19) United States
(12) Patent Application Publication
(10) Pub. No.: US 2017/0106510 A1
(43) Pub. Date: Apr. 20, 2017

(54) COMPONENT REMOVAL DEVICE

(71) Applicants: Margaret Galtieri, Danbury, CT (US); Jason Galtieri, Champaign, IL (US)

(72) Inventors: Margaret Galtieri, Danbury, CT (US); Jason Galtieri, Champaign, IL (US)

(21) Appl. No.: 15/296,427

(22) Filed: Oct. 18, 2016

Related U.S. Application Data
(60) Provisional application No. 62/243,805, filed on Oct. 20, 2015.

(51) Int. Cl. B25B 27/00; H05K 13/00; F21V 33/00

(52) U.S. Cl. CPC B25B 27/00; F21V 33/0084; H05K 13/0007; F21Y 2115/10

(57) ABSTRACT

A component removal device that is configured to access hard to reach electrical components in a networking system to facilitate fast and easy removal of the electrical component is provided. In embodiments, the component removal device includes a handle, a body portion extending distally from the handle and an end effector that is configured to engage the electrical component to facilitate removal of the electrical component from the networking system. In embodiments, the end effector includes at least one prong that is positioned to engage the electrical component to allow the electrical component to be pulled from a data port of a switch of the networking system. The component removal device may include an illuminating device to improve visualization of the end effector and the electrical component to be removed. In embodiments, the at least one prong includes two spaced prongs which may be formed of a rigid material, or alternatively, of a resilient material.

### BACKGROUND

1. Technical Description

The present disclosure is directed to a removal device for hard to access electrical components and, more particularly, to a removal device for a component of a network system, e.g., a gigabit interface converter (“GBIC”), or small form-factor pluggable (“SFP”) module.

2. Background of Related Art

Networking systems typically include switches that include a multiplicity of closely spaced dataports. Each of the dataports receives a GBIC or SFP module which converts high speed optical signals to electrical or digital signals and vice versa. When the GBIC or SFP requires removal from the dataport, due to its positioning as discussed in further detail below, it is difficult to access and grasp.

Referring to FIGS. 1-4, one example of an electrical component, e.g., a GBIC 10, includes a body 12 defining a pair of optical bore ports 13 that is dimensioned to be received within a respective dataport 100 (FIG. 4) of a switch 102 of a networking system. The GBIC 10 includes a pivotal clasp 14 that is pivotal from an unlocked position (FIG. 1) to a locked position (FIG. 3) to secure the GBIC 10 within the dataport 100 of the switch 102. When the GBIC 10 is locked in the dataport 100 of the switch 102, the clasp 14 is positioned nearly flush with the entrance to the dataport 100 adjacent a face of the switch 102. The positioning of the clasp 14 in relation to the dataport 100 and face of the switch 102 makes it difficult to access the GBIC 10 for removal. As shown in FIG. 4, access to an individual GBIC 10 is rendered even more difficult by the attachment of the fiber optic cables 110 to the GBIC 10 within the closely spaced dataports 100.

It would be desireable to have a device configured to access electrical components such as GBIC's and SFP's quickly and easily to speed up the removal process.

### SUMMARY

In one aspect of the disclosure, a component removal device includes a handle, a central body portion extending distally from the handle, and a pair of spaced prongs extending distally from the central body portion. Each of the spaced prongs has a longitudinally extending portion and a transversely extending portion.

In embodiments, each of the pair of spaced prongs is formed of a rigid material.

In some embodiments, each of the spaced prongs is L-shaped.

In certain embodiments, each of the spaced prongs has a curved configuration.

In embodiments, the longitudinally extending portions of the pair of spaced prongs are parallel to each other.

In some embodiments, the longitudinally extending portions of the pair of spaced prongs converge towards each other.

In another aspect of the disclosure, the component removal device includes a handle defining a longitudinal axis, a central body portion extending distally from the handle, and an end effector including at least one prong. The at least one prong extends in a direction transversely to the longitudinal axis.

In embodiments, the component removal device includes an illuminating device directed to illuminate an area about the end effector.

In some embodiments, the illuminating device includes an LED.

In certain embodiments, the handle, the central body portion, and a portion of the end effector are integrally molded, wherein the portion of the end effector is molded about the at least one prong.

In embodiments, the at least one prong includes a pair of prongs.

In some embodiments, the handle, the central body portion, and the portion of the end effector are formed of a polymeric material.

In certain embodiments, the pair of prongs is formed from a metallic material.

In embodiments, the component removal device is integrally molded as a single piece.

In some embodiments, each of the pair of prongs is formed of a resilient material.

In certain embodiments, each of the prongs includes a longitudinally extending portion and a transversely extending portion, wherein the longitudinally extending portion of each prong of the pair of prongs is parallel to the other prong. Alternately, the longitudinally extending portion of each prong of the pair of prongs converges towards the other prong or diverges away from the other prong.

### BRIEF DESCRIPTION OF THE DRAWINGS

Various embodiments of the presently disclosed component removal device are described herein below with reference to the figures, wherein:

FIG. 1 is a side perspective view of a prior art gigabit interface converter (“GBIC”) with a clasp in an open position;

FIG. 2 is a top view of the GBIC shown in FIG. 1 and a pair of optical fiber cables prior to attachment of the cables to the GBIC;

FIG. 3 is a side perspective view of the GBIC shown in FIG. 1 with the clasp in the closed position;

FIG. 4 is a view of a switch of a network system with a plurality of GBICs as shown in FIG. 1 inserted within dataports of the switch and fiber optic cables received within the dataports;

FIG. 5 is a top perspective view of one embodiment of the presently disclosed component removal device;

FIG. 6 is a side view of the distal end of one embodiment of the presently disclosed component removal device;

FIG. 7 is a side view of the distal end of another embodiment of the presently disclosed component removal device;

FIG. 8 is a top view of the distal end of yet another embodiment of the presently disclosed component removal device;

FIG. 9 is a top view of the distal end of another embodiment of the presently disclosed component removal device;

FIG. 10 is a top view of the distal end of yet another embodiment of the presently disclosed component removal device;

FIG. 11 is a side perspective view of the component removal device shown in FIG. 5 engaged with a GBIC with the clasp in a substantially closed position;

FIG. 12 is a side perspective view of the component removal device shown in FIG. 5 engaged with a GBIC with the clasp in a partially open position;

FIG. 13A is a bottom view of an alternate embodiment of the presently disclosed component removal device;

FIG. 13B is an enlarged perspective view of a distal portion of the component removal device shown in FIG. 13A;

FIG. 14A is a side view of another alternate embodiment of the presently disclosed component removal device; and

FIG. 14B is an enlarged perspective view of a distal portion of the component removal device shown in FIG. 14A.

### DETAILED DESCRIPTION OF EMBODIMENTS

The presently disclosed component removal device or GBIC PIC will now be described in detail with reference to the drawings in which like reference numerals designate identical or corresponding elements in each of the several views. In this description, the term “proximal” is used generally to refer to the portion of the apparatus that is closer to a technician, while the term “distal” is used generally to refer to the portion of the apparatus that is farther from the technician.

The presently disclosed component removal device is configured to access hard to reach electrical components in a networking system to facilitate fast and easy removal of the electrical component. In embodiments, the component removal device includes a handle, a body portion extending distally from the handle and an end effector that is configured to engage the electrical component to facilitate removal of the electrical component from the networking system. In embodiments, the end effector includes at least one prong that is positioned to engage the electrical component to allow the electrical component to be pulled from a data port of a switch of the networking system. The component removal device may include an illuminating device to improve visualization of the end effector and the electrical component to be removed. In embodiments, the at least one prong includes two spaced prongs which may be formed of a rigid material, or alternatively, of a resilient material.

Referring to FIGS. 5-7, the component removal device 200 includes a handle 202, a central body portion 204, and an end effector 206. The handle 202 can assume any of a variety of configurations that allow a technician to securely grasp the device 200. In embodiments, the handle 202 may include a substantially cylindrical handgrip 210 that includes longitudinal grooves or a ribbed surface that improve grip ability of the handgrip 210. In embodiments, the handgrip 210 may include anti-skid coatings or configurations.

The central body portion 204 of the removal device 200 has a first end supported on the handle 202 and a second end spaced from the handle 202. The central body portion 204 should be of a length to facilitate access to an electrical component, e.g., GBIC 10, through the fiber optic cables 110 when the fiber optic cables 110 are attached to the GBIC 10.

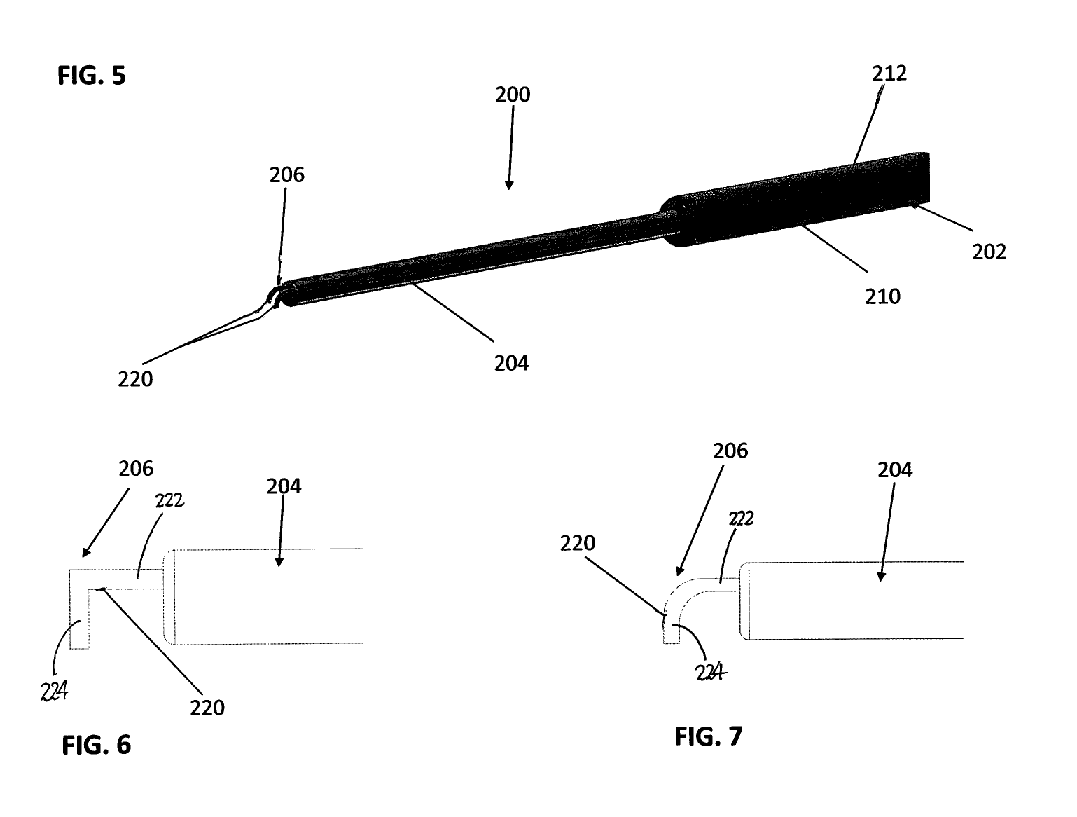

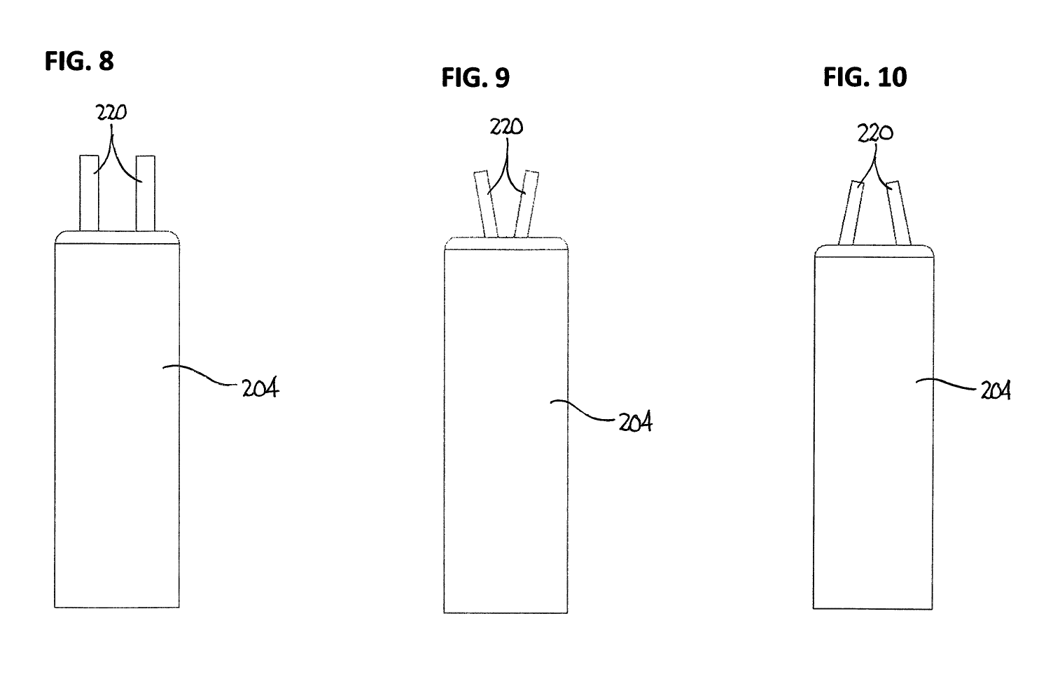

In embodiments, the end effector 206 includes at least one prong, e.g., two prongs 220, that extend from the end of the central body portion 204 and are spaced from the handle 202. In some embodiments, the prongs 220 are spaced from each other a distance less than the width of the component being removed, e.g., a GBIC, and have a longitudinally extending portion 222 and a transversely extending portion 224. Alternatively, the prongs can extend transversely from the central body portion 204. In certain embodiments, each of the prongs 220 defines a substantially L-shape (FIG. 6). By providing two spaced prongs 220, the force of the removal device 200 can be applied evenly across the GBIC 10 to allow the GBIC 10 to be pulled from the tight confines of the dataport 100. The prongs 220 are sufficiently rigid to apply a removal force sufficient to pull the GBIC 10 from the dataport 100 of the switch 102. Alternately, the prongs 220 of the end effector 206 may have a curved configuration (FIGS. 5 and 7). In addition, the prongs 220 may extend in a direction parallel to each other (FIG. 8) diverge from each other (FIG. 9), or converge towards each other (FIG. 10).

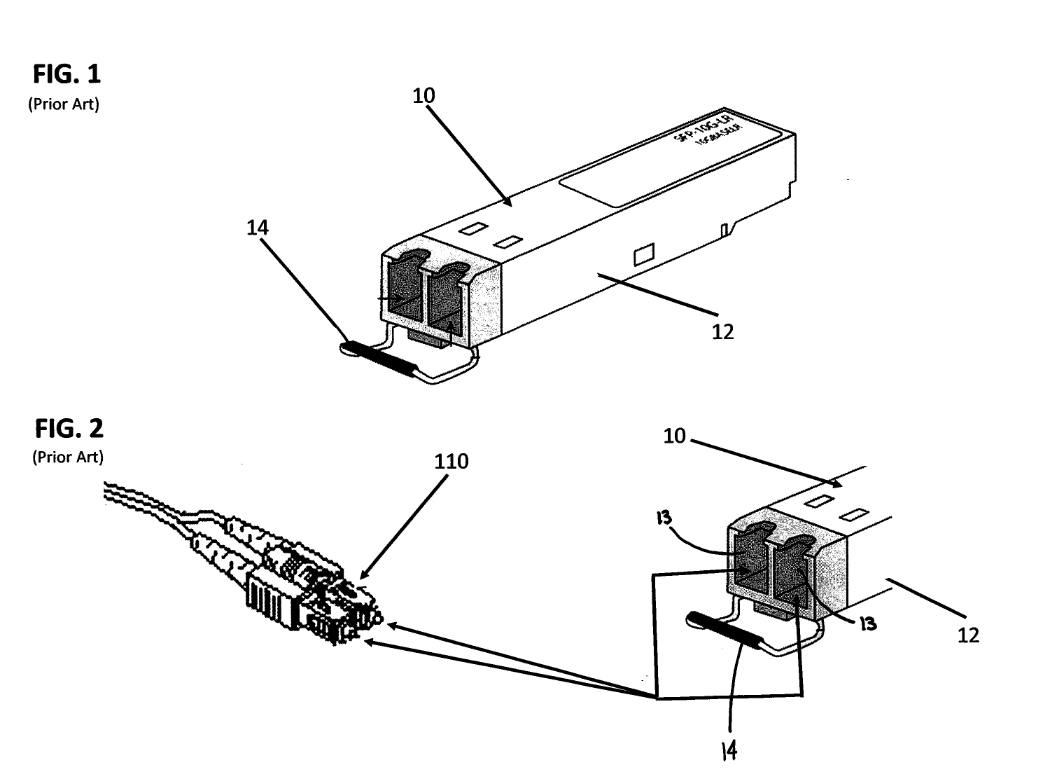

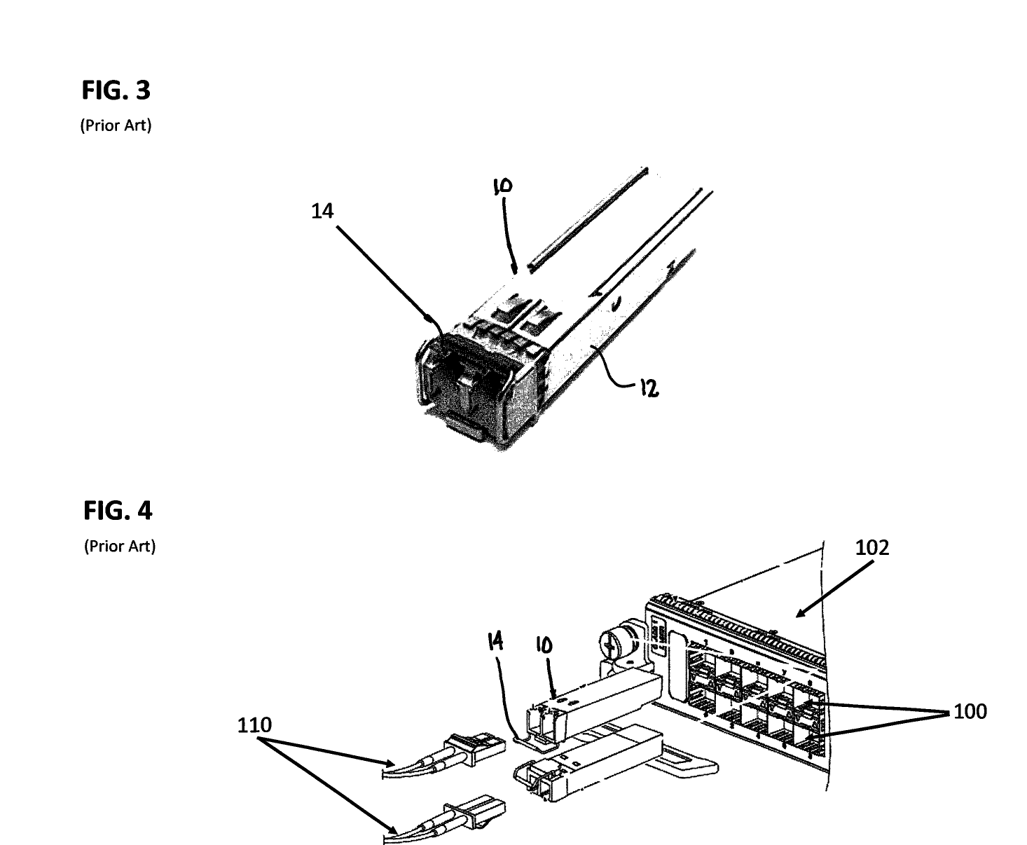

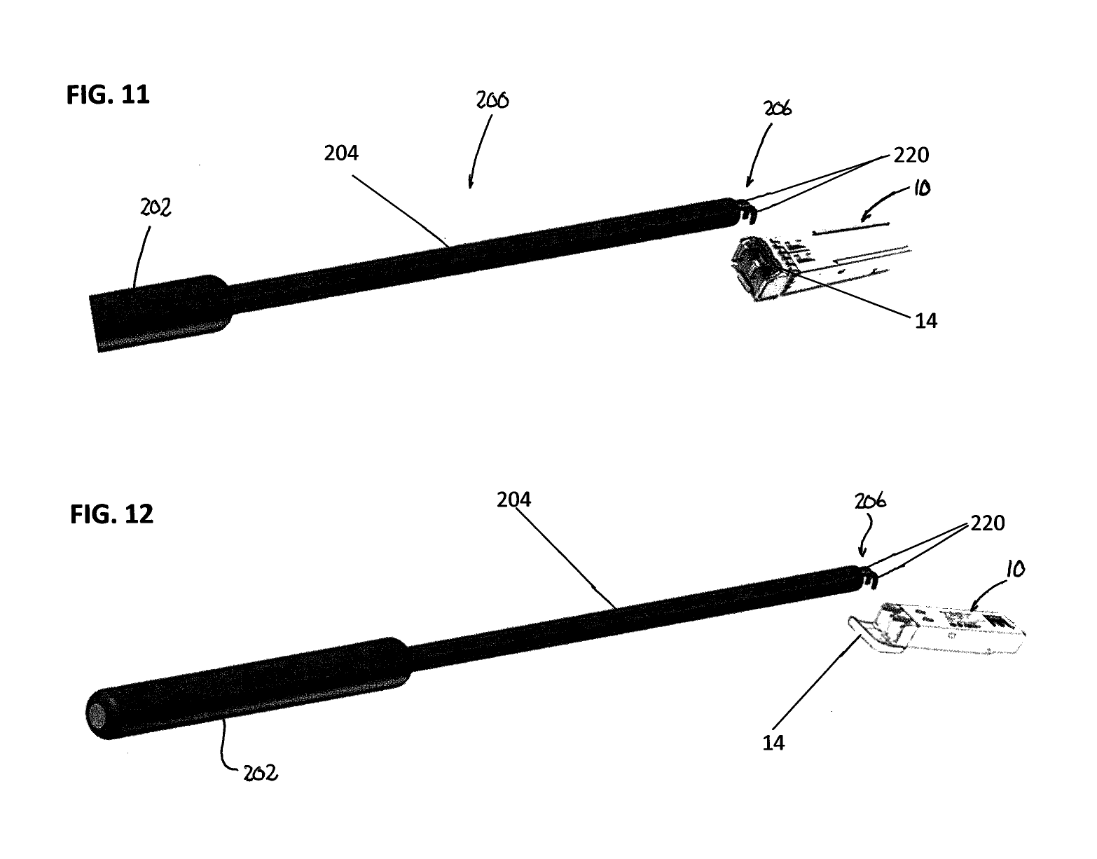

Referring to FIGS. 11 and 12, in use, the prongs 220 of the end effector 206 are positioned between the rear wall of the switch 102 (FIG. 4) and the clasp 14 of the GBIC 10 and pulled in a direction to remove the GBIC 10 from the dataport 100 (FIG. 4) of the switch 102. When this step is executed, the clasp 14 of the GBIC 10 will pivot away from the body 12 as shown in FIG. 1 to facilitate removal of the GBIC 10 from the dataport 100.

Although the component removal device 200 is illustrated in use for removal of a GBIC 10, it is envisioned that the component removal device 200 may be used for removal of a variety of different electrical and mechanical components from a variety of different systems.

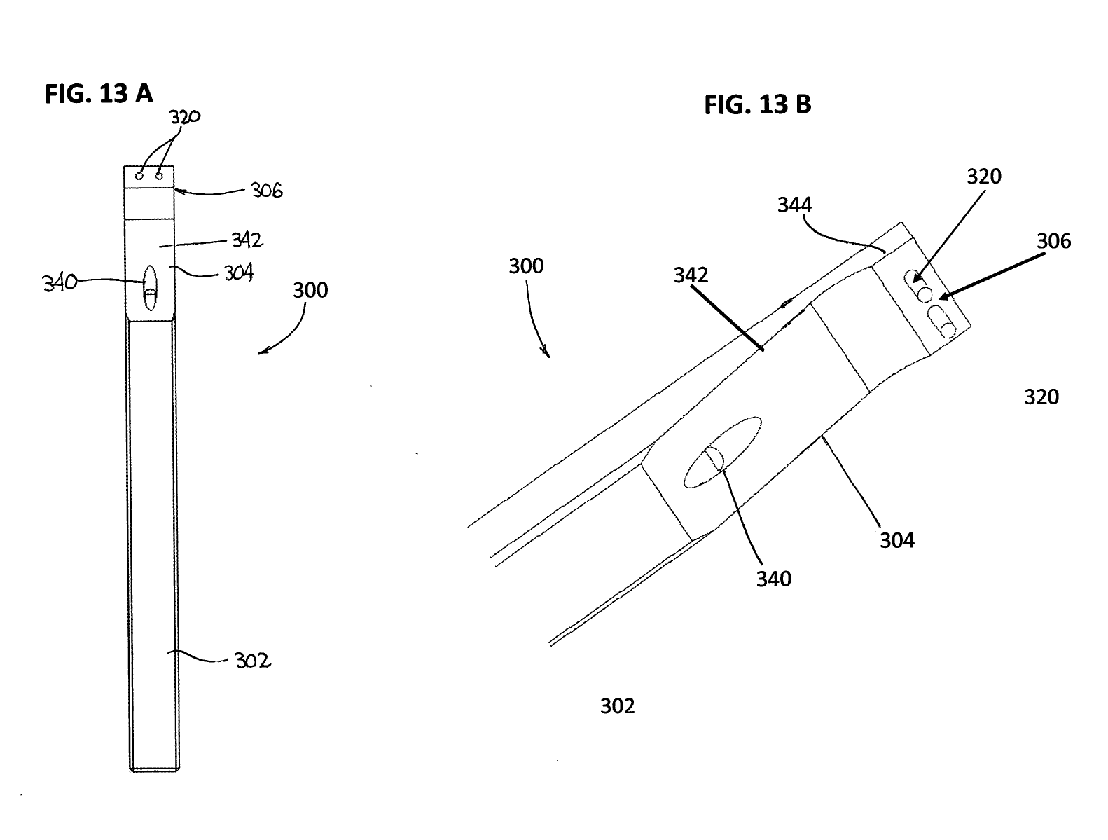

FIGS. 13A and 13B illustrate an alternate embodiment of the presently disclosed component removal device shown generally as component removal device 300. The component removal device 300 includes a handle 302, a central body portion 304, and an end effector 306. The end effector 306 includes a pair of spaced prongs 320 that extend downwardly from a distal portion of the end effector 306. In embodiments, the prongs 320 include cylindrical posts although other configurations are envisioned. In embodiments, the handle 302, the central body portion 304, and a portion of the end effector 306 are molded as a single piece from a polymeric material or the like about the posts which may be formed of metal, e.g., stainless steel. Alternately, other materials of construction are envisioned.

The component removal device 300 also includes an illuminating device 340 supported on the device for illuminating the area about the end effector 306. In embodiments, the central body portion 304 defines a tapered surface 342 that decreases in width in the distal direction and the end effector 306 includes a transverse portion 344 from which the prongs 320 extend. The illuminating device 340 is positioned on the tapered surface 342 of the central portion 304 and is positioned to illuminate the area adjacent the end effector 306. In embodiments, the illuminating device 340 includes a light emitting diode (LED) although other types of illuminating devices are envisioned. A source of power, e.g., a battery or piezoelectric element, for the illuminating device 340 can be supported on the device 300. For example, the handle 302 may include a battery or other power supply device.

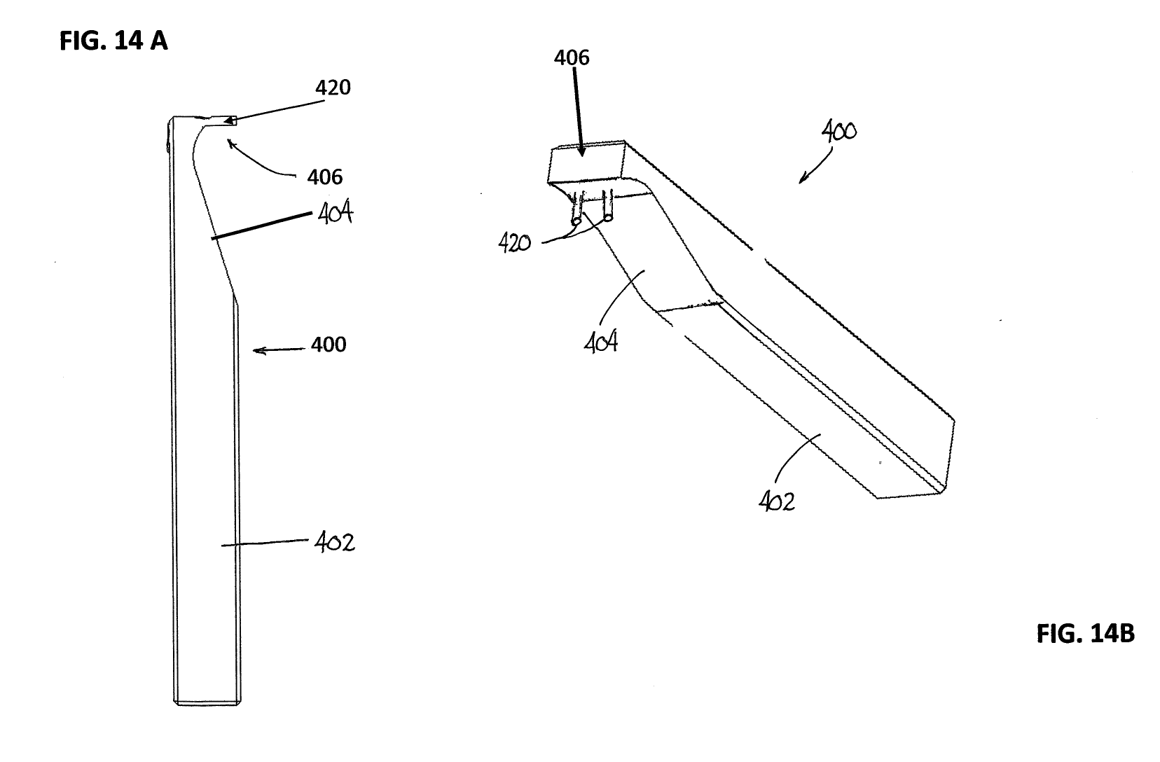

FIGS. 14A and 14B illustrate another embodiment of the presently disclosed component removal device shown generally as component removal device 400. Component removal device 400 includes a handle 402, a central body portion 404, and an end effector 406. The component removal device 400 differs from component removal device 300 (FIG. 11A) in that in component removal device 400, prongs 420 are molded together with the handle 402, the central body portion 404 and the end effector 406.

Persons skilled in the art will understand that the devices and methods specifically described herein and illustrated in the accompanying drawings are non-limiting exemplary embodiments. It is envisioned that the elements and features illustrated or described in connection with one exemplary embodiment may be combined with the elements and features of another without departing from the scope of the present disclosure. As well, one skilled in the art will appreciate further features and advantages of the disclosure based on the above-described embodiments. Accordingly, the disclosure is not to be limited by what has been particularly shown and described, except as indicated by the appended claims.

What is claimed is:

1. A component removal device comprising:
a handle;
a central body portion extending distally from the handle; and
a pair of spaced prongs extending distally from the central body portion, each of the spaced prongs having a longitudinally extending portion and a transversely extending portion.

2. The component removal device of claim 1, wherein each of the pair of spaced prongs is rigid.

3. The component removal device of claim 1, wherein the each of the spaced prongs is L-shaped.

4. The component removal device of claim 1, wherein each of the prongs has a curved configuration.

5. The component removal device of claim 1, wherein the longitudinally extending portions of the pair of spaced prongs are parallel to each other.

6. The component removal device of claim 1, wherein the longitudinally extending portions of the pair of spaced prongs converge towards each other.

7. A component removal device comprising:
a handle defining a longitudinal axis;
a central body portion extending distally from the handle; and
an end effector including at least one prong, the at least one prong extending in a direction transversely to the longitudinal axis.

8. The component removal device of claim 7, further including an illuminating device directed to illuminate an area about the end effector.

9. The component removal device of claim 8, wherein the illuminating device includes an LED supported on the central body portion.

10. The component removal device of claim 7, wherein the handle, the central body portion, and a portion of the end effector are integrally molded, the portion of the end effector being molded about the at least one prong.

11. The component removal device of claim 10, wherein the at least one prong includes a pair of prongs.

12. The component removal device of claim 11, wherein the handle, the central body portion, and the portion of the end effector are formed of a polymeric material.

13. The component removal device of claim 12, wherein the pair of prongs is formed from a metallic material.

14. The component removal device of claim 7, wherein the component removal device is integrally molded as a single piece.

15. The component removal device of claim 7, wherein the at least one prong includes a pair of prongs.

16. The component removal device of claim 7, wherein each of the pair of prongs is rigid.

17. The component removal device of claim 7, wherein the each of the pair of prongs is L-shaped.

18. The component removal device of claim 7, wherein each of the pair of prongs has a curved configuration.

19. The component removal device of claim 7, wherein each of the prongs includes a longitudinally extending portion and a transversely extending portion, the longitudinally extending portion of the pair of spaced prongs being parallel to each other.

20. The component removal device of claim 1, wherein each of the pair of prongs includes a longitudinally extending portion and a transversely extending portion, the longitudinally extending portion of the pair of prongs converging towards each other.
